(19) United States
(12) Patent Application Publication
(10) Pub. No.: US 2008/0023057 A1
(43) Pub. Date: Jan. 31, 2008

(54) Thermoelectric Conversion Module, and Thermoelectric Power Generating Device and Method, Exhaust Heat Recovery System, Solar Heat Utilization System, and Peltier Cooling and Heating System, Provided Therewith

(75) Inventors: Kenichiro Nakajima, Chichibu-shi (JP); Yoshio Hara, Chichibu-shi (JP)

Correspondence Address: SUGHRUE MION, PLLC, 2100 PENNSYLVANIA AVENUE, N.W., SUITE 800, WASHINGTON, DC, 20037, US

(73) Assignee: SHOWA DENKO K.K., Minato-ku, Tokyo (JP)

(21) Appl. No.: 11/664,421

(22) PCT Filed: Nov. 1, 2005
(86) PCT No.: PCT/JP05/20395

§ 371 Date: Apr. 2, 2007

Related U.S. Application Data
(60) Provisional application No. 60/625,950, filed on Nov. 9, 2004.

(30) Foreign Application Priority Data
Nov. 2, 2004 (JP) 2004-319731

(51) Int. Cl. H01L 35/08; H01L 35/28; H01L 35/32; H01L 35/34

(52) U.S. Cl. 136/201; 136/204; 136/205; 136/206; 136/224; 136/230

(57) ABSTRACT

The thermoelectric conversion module is provided, comprising a plurality of thermoelectric elements, and respective thermoelectric elements are electrically connected by metal caps attached to both ends of each thermoelectric element. In addition, the metal cap may be integrally formed with electrodes on both ends of each thermoelectric element.

Priority is claimed to Japanese application No. 2004-319731, filed Nov. 2, 2004, which are incorporated herein by reference. This application also claims the benefit pursuant to 35 U.S.C. §119(e) (1) of U.S. Provisional Applications No. 60/625950 filed on Nov. 9, 2004.

### TECHNICAL FIELD

The present invention relates to the structure of a thermoelectric conversion module that directly converts heat into electricity due to the Seebeck effect, and a thermoelectric power generating device and method, an exhaust heat recovery system, a solar heat utilization system, and a Peltier cooling and heating system, provided with this thermoelectric conversion module.

### BACKGROUND ART

Recently, due to regulations of carbon dioxide gas emissions for the prevention of global warming, and concern over the depletion of crude oil resources, a thermoelectric power generating system that directly converts waste heat into electricity is drawing attention.

A thermoelectric power generating system refers to an entire system in which thermoelectric elements constructed with both a p-type semiconductor and an n-type semiconductor are connected in series, and a temperature difference is generated at both ends of the semiconductors by having one end as a high temperature heat source and the other end at atmosphere or a cool temperature in order to extract the electromotive force generated thereby as electrical power. A thermoelectric conversion module generally refers to a construction from among structures having this construction, comprising thermoelectric elements, electrodes that connect the thermoelectric elements, and insulation plates.

A conventional thermoelectric conversion module is produced by thermally spraying metal such as copper on ceramic plates such as alumina to produce electrodes and joining thermoelectric elements to these electrodes by means of silver soldering or the like. Therefore there is concern that as the temperature difference grows larger, a large thermal stress is generated due to the different thermal expansion coefficients of the respective substances that construct the module such as thermoelectric elements, electrodes and insulating plates, which could lead to destruction of the module itself depending on the operating conditions. (Refer to Non-Patent Document 1)

In order to alleviate this thermal stress, attempts have been made in which a substance which serves as a buffer layer is coated on the thermoelectric element to absorb the thermal expansion, or the shape of the electrode is devised so as to reduce the stress. However, since each of these attempts lacks durability and reliability, they are yet to achieve practical applications.

Moreover, a method of inserting thermal and electrical conductive grease between the electrode and the element has been considered. However, since these methods also have a problem with reliability, they have not achieved practical applications either at this point. (Refer to Patent Documents 1, 2, 3, 4 and 5) Furthermore, if a module is produced by crimping the electrode and the element using a mechanical means such as screws or springs instead of joining them, in order to reduce the thermal stress mentioned above, there is the possibility of enhanced durability and reliability, however, there is a problem of reduced performance.

Moreover, there has been an example of employing a crimp-style terminal as an electric current output terminal for prevention of defects due to soldering. However, a thermoelectric conversion module using these techniques has not achieved practical application either at this point. (Refer to Patent Document 6)

Non-Patent Document 1: Makoto Sakata, “Engineering of thermoelectric energy conversion”

Patent Document 1: Japanese Patent No. 3056047

Patent Document 2: Japanese Patent Laid-Open No. Hei 10-229224

Patent Document 3: Japanese Patent Laid-Open No. 2000-216444

Patent Document 4: Japanese Patent Laid-Open No. 2001-194022

Patent Document 5: Japanese Patent Laid-Open No. 2002-185050

Patent Document 6: Japanese Unexamined Patent Application, First Publication No. 2004-22574.

### DISCLOSURE OF INVENTION

In order to bring a thermoelectric conversion system into common application, conversion efficiency, reliability and durability need to be achieved at high level. However, it is difficult to achieve high performance and high durability at the same time with a thermoelectric conversion module of conventional construction, and a module with a new structure is needed.

Moreover, in the conventional method, there were only the options of either introducing a buffer layer at the cost of performance in order to improve reliability by reducing thermal stress, or employing mechanical junctions at the cost of performance.

The present invention, in consideration of the above problems, aims to contribute to the popularization of thermoelectric conversion systems by providing a thermoelectric conversion module that achieves high reliability and performance.

The present inventor has discovered a highly productive construction whereby it is possible to achieve both relaxation of thermal stress, and high performance, using neither a conventional spring method nor a chemical joining method, by joining an element and an electrode of a thermoelectric conversion module by means of attaching a cap to the thermoelectric element. Moreover, a thermoelectric conversion module is provided, comprising a plurality of thermoelectric elements, and respective thermoelectric elements are electrically connected by metal caps attached to both ends of each thermoelectric element. In addition, the metal cap may be integrally formed with electrodes on both ends of each thermoelectric element. The above-described achievements have resulted in the invention of the present application.

(1) A thermoelectric conversion module of the present invention is characterized in that an electrical connection of a thermoelectric element is carried out by a metal cap.

(2) In the above-described thermoelectric conversion module, each metal cap is integrally formed with an electrode of the thermoelectric element.

(3) The above thermoelectric conversion module of the present invention is characterized in that an insulating material is coated on at least one or more faces of the electrode, and the cap is integrated to a face of the electrode that is not coated with the insulating material.

(4) The thermoelectric conversion module of the present invention is characterized in that a p-type thermoelectric element and an n-type thermoelectric element are alternately connected via the electrodes, and the metal cap is respectively attached to both end parts of the p-type thermoelectric element and to both end parts of the n-type thermoelectric element, and the thermoelectric element and the electrode are connected via the metal cap.

(5) The thermoelectric conversion module of the present invention is characterized in that the thermoelectric element is configured in a block form, and the metal cap is attached to both end parts of the thermoelectric element of each block.

(6) The thermoelectric conversion module of the present invention is characterized in that a plurality of the p-type thermoelectric elements and the n-type thermoelectric elements are connected via the metal caps on their both end parts, and these are arranged in lengthwise and crosswise directions to form a thermoelectric conversion module set, and the electrodes on one side of each of the thermoelectric elements are arranged on one face side of the thermoelectric conversion module set, and the electrodes on the other side of each of the thermoelectric elements are arranged on the other face side of the arrayed thermoelectric conversion module set.

(7) The thermoelectric conversion module of the present invention is characterized in that a heat exchanger that contacts with the electrodes of each of the thermoelectric elements via an insulating material is provided on one face side of the thermoelectric conversion module set, and a heat exchanger that contacts with the electrodes of each of the thermoelectric elements via an insulating material is provided on the other face side of the thermoelectric conversion module set.

(8) A thermoelectric power generating device of the present invention is characterized in that it is provided with a thermoelectric conversion module according to any one of the above aspects.

(9) A thermoelectric power generating method of the present invention is characterized in that it uses a thermoelectric conversion module according to any one of the above aspects.

(10) A waste heat recovery system of the present invention is characterized in that it is provided with a thermoelectric conversion module according to any one of the above aspects.

(11) The solar heat utilization recovery system of the present invention is characterized in that it is provided with a thermoelectric conversion module according to any one of the above aspects.

(12) A Peltier cooling and heating system of the present invention is characterized in that it uses a thermoelectric conversion module according to any one of the above aspects.

(13) A radioisotope thermoelectric power generation system of the present invention is characterized in that it uses a thermoelectric conversion module according to any one of above aspects.

(14) A biomass system is characterized in that it uses a thermoelectric conversion module according to any one of above aspects.

(15) A thermoelectric element conversion element having at least one metal cap.

According to the present invention, a thermoelectric conversion module that achieves both high reliability and high performance can be manufactured at a low cost, and it is expected to bring thermoelectric conversion systems into common applications.

Also, according the present invention, a thermoelectric conversion module of both high reliability and high performance can be manufactured at low cost, with the aim of providing an excellent thermoelectric power generating device and thermoelectric power generating method as well as an exhaust heat recovery system, a solar heat utilization system, a radioisotope thermoelectric power generation system, a biomass system, and a Peltier cooling and heating system.

### BRIEF DESCRIPTION OF THE DRAWINGS

FIG. 1 is a perspective view showing a principal part of a thermoelectric conversion module relating to one embodiment of the present invention.

FIG. 2 is a perspective view showing an example of a thermoelectric conversion module set that shows an example of a combination of a plurality of the thermoelectric conversion modules.

FIG. 3 is a perspective view showing an example of a thermoelectric power generating device having the thermoelectric conversion module set shown in FIG. 2.

FIG. 4 is a perspective view showing an example of a conventional typical thermoelectric conversion module.

FIG. 5 is a perspective view showing a construction of a conventional typical thermoelectric conversion module set.

### BRIEF DESCRIPTION OF THE REFERENCE SYMBOLS

1 Electrode, 2 Cap, 3 p-type thermoelectric element, 4 n-type thermoelectric element, 5 Electric current terminal, 6 Heat exchanger, A Thermoelectric conversion module, B Thermoelectric conversion module set, C Thermoelectric conversion system, D Thermoelectric conversion module set, 10 Electrode, 30, 40 Thermoelectric element, 50 Thermoelectric conversion module

### BEST MODE FOR CARRYING OUT THE INVENTION

Hereinafter, a best mode for carrying out the present invention is described, with reference to the appended drawings.

As an essential element for constructing a thermoelectric module of the present invention, a thermoelectric element conversion element having at least one metal cap is used.

In a thermoelectric module of the present invention, electrical connection of a plurality of thermoelectric elements can be carried out via metal caps.

The material of the metal cap is not particularly limited. However, an electrically conductive cap, the material of which has a thermal expansion coefficient that is equal or close to that of the substance forming the thermoelectric element is preferable. For example, stainless steel, copper, iron, silver, gold or the like can be used for a thermoelectric element having a high linear expansion coefficient, and molybdenum, zirconium, titanium, tungsten or the like can be used for a thermoelectric element having a low linear expansion coefficient.

Moreover, to prevent gaps occurring due to a temperature rise in the thermoelectric element, it is also effective to load particles of alloyed metal or other metal that converts into a liquid state at high temperature between the cap and the thermoelectric element.

The shape of the metal cap employed in the present invention is not particularly limited. However, it is preferable that the metal cap be cylindrical if the thermoelectric element has a round column shape, and a bottom face of the metal cap may be a flat plate or may even have a curvature. However, the height of the cap is preferably half the height of the thermoelectric element or less. Moreover, by providing a small hole on the bottom face of the cap, or by forming a groove in one part of the side face of the cap, a mechanism for releasing any remaining air in the gap between the cap and the thermoelectric element that has expanded due to the temperature rise, can also be provided.

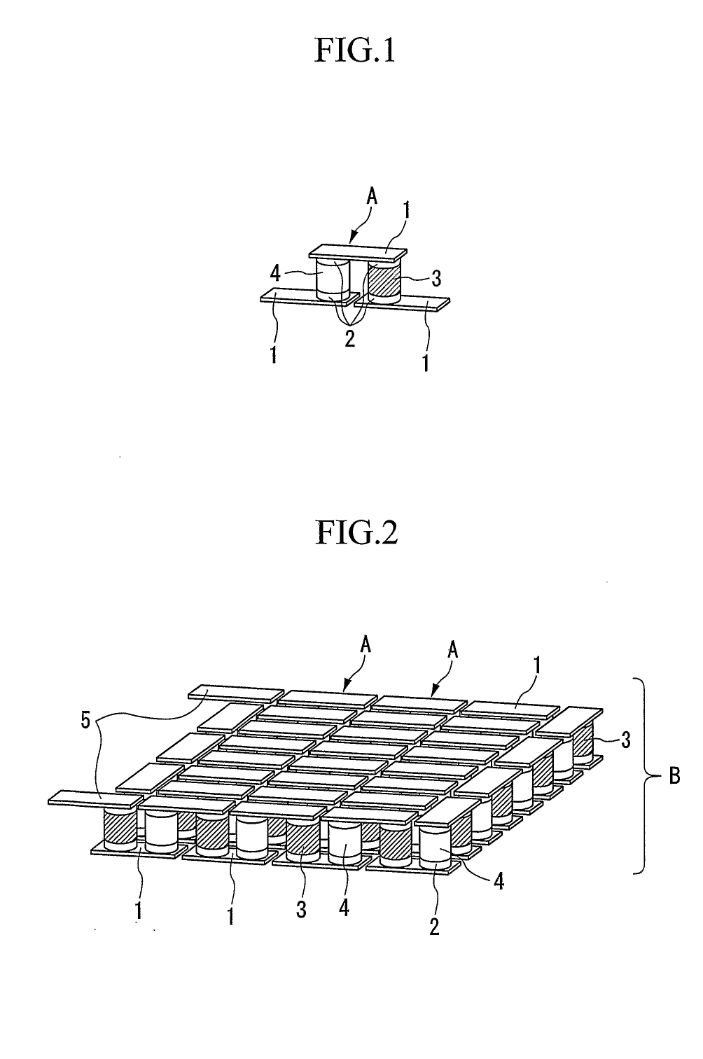

An example of a specific connection structure is shown in FIG. 1 in which bottomed cylindrical shaped caps 2 are respectively mechanically pressed onto both end parts of a column shaped p-type thermoelectric element 3 and onto both end parts of an n-type thermoelectric element 4, and rectangular plate shaped electrodes 1 are connected to the caps 2.

In this embodiment, a thermoelectric conversion module A is constructed such that the column shaped p-type thermoelectric element 3 and n-type thermoelectric element 4 are arranged in parallel, and the cap 2 on one end side of the p-type thermoelectric element 3 and the cap 2 of the n-type thermoelectric element 4 are connected by one electrode 1, and another electrode 1 is connected to the cap 2 on the other end side of the p-type thermoelectric element 3, and furthermore, another further electrode 1 is connected to the cap 2 on the other end side of the n-type thermoelectric element 4. Furthermore, the preferable width of the electrode 1 used here is substantially equal to the diameter of the p-type thermoelectric element 3 and the n-type thermoelectric element 4.

Moreover, a plurality of thermoelectric conversion modules A constructed as described above is connected in series so as to alternately align the p-type thermoelectric elements 3 and the n-type thermoelectric elements 4, while the alternately connected thermoelectric conversion modules A are arranged in zigzags in parallel in lengthwise and crosswise directions in plan view to construct a thermoelectric conversion module set B as shown in FIG. 2. In a series of electrodes 1 of the thermoelectric conversion module set B arranged in series, the electrode 1 on one end side, and the electrode 1 on the other end side of the module set B are made electric current terminals 5.

The thermoelectric conversion modules A are arranged in a flat plate shape in lengthwise and crosswise directions, forming the thermoelectric conversion module set B. However, the shape of the thermoelectric conversion module set B may be made in different shapes other than the flat plate shape arrangement, such as a cylindrical arrangement or the like, depending on the heat source to which it is to be applied.

The cap 2 and the electrode 1 can be joined when heated at 700° C. using soldering materials such as silver solder. However, the cap 2 can be pre-joined with the electrode 1, and in this way productivity can be further improved. Moreover, a structure is also possible in which the electrode 1 and the cap 2 are integrated, and by coating a metal or conductive ceramic that function as a diffusion barrier layer on the inner face side of the cap 2, or by using them as a construction material of the cap, a step of coating these as a layer on the thermoelectric elements can be omitted, so that the productivity of the thermoelectric conversion module A can be further improved.

Moreover, if the back side of the electrode 1 is pre-coated with an insulation layer such as ceramic, an insulation plate is no longer required so that production cost can be reduced. The material of the insulation layer is not particularly limited. However, oxide ceramics and various types of insulation ceramics can be employed, and a preferable material is alumina, which can be commonly acquired at a low cost.

The thickness of the insulation layer needs to be selected according to the shape of the thermoelectric conversion module to which it is to be applied. However, a preferable thickness is approximately 100 nm.

By employing the structure of the present invention, a stress load caused by heat expansion of the thermoelectric elements 3 and 4 can be absorbed due to the presence of the cap 2. Furthermore, since the present invention provides a structure that alleviates stress, in which the electrode 1 is not fixed but is mechanically pressed in, the pair of the p-type thermoelectric element 3 and the n-type thermoelectric element 4 can be constructed using materials that have different thermal expansion coefficients. For example, a filled Skutterudite sintered compact can be used for both the p-type and the n-type thermoelectric elements, or a Zn₃Sb₄ type element, a cobalt oxide type element, a Mn—Si type element, a Mg—Si type element, a Bi—Te type element, a Pb—Te type element, a Heusler/half-Heusler type material, or a Si—Ge type material can be employed exclusively or in an appropriate combination for at least one of either the p-type or the n-type thermoelectric elements.

For example, at medium to high temperature (300 to 500° C.), a filled Skutterudite sintered compact, a cobalt oxide layer, a Zn₃Sb₄ type material, a Mn-Si type material, or a Mg—Si type material can be used, and a Bi—Te type material can be used at around room temperature.

For example, since a thermoelectric conversion material having a filled Skutterudite structure has a low heat conductivity even among intermetallic compounds such as CoSb₃, which is a conventional thermoelectric conversion material having a Skutterudite type crystal structure, it is a preferable material at high temperatures in particular.

Filled Skutterudite type alloy is an intermetallic compound expressed by the general formula RT₄Pn₁₂ (where R is a rare earth metal, T is a transition metal, and Pn is an element such as P, As or Sb), in which atomic elements having a large mass such as a rare earth metal (R) are filled into some interstitial that exist in a crystal of a filled Skutterudite type structure expressed by the general formula TPn₃ (where T is a transition metal and Pn is one of the elements such as P, As or Sb).

Moreover, since filled Skutterudite type thermoelectric conversion material not only enables separate production of a p-type and n-type material by appropriate selection of a transition metal T, but is also not anisotropic so that the crystals therein do not need to be oriented, the production process is simple and the productivity is excellent.

Fe in the transition metal site can also be replaced by Ni for an n-type filled Skutterudite element YbCo₄Sb₁₂.

Furthermore, it is also preferable to use REₓ(Fe_{1-y}M_{y})₄YbCo₄Sb₁₂ (RE is at least one type selected from La and Ce, and M is at least one type selected from the group of Ti, Zr, Sn and Pb. 0<x≦1, 0<y<1) as a p-type thermoelectric conversion material, and it is preferable to use REₓ(Co_{1-y}M_{y})₄SbCO₄Sb₁₂ (RE is at least one type selected from La and Ce, and M is at least one type selected from the group of Ti, Zr, Sn and Pb. 0<x≦1, 0<y<1) as an n-type thermoelectric conversion material.

The production method of the thermoelectric conversion material is not particularly limited. However, an example of a method of producing an element can be given, in which a powder produced by quenching and solidifying materials that have been weighed to become the targeted composition and that have been melted in an inert gas atmosphere, is subjected to plasma sintering and heat application.

As a quenching method, a strip casting method and other commonly known quenching methods for dissolving metal can be used. However, the strip casting method is preferable from an industrial viewpoint.

When quenching, a preferable cooling speed is 1×10²K/second or more, in a range of 1400° C. to 400° C., and it is more preferably 1×10²K/second or more, and 1×10⁴K/second or less. If the cooling speed is lower than this, the phases separate resulting in a large fluctuation in material components due to pulverization, and if the cooling speed is higher than this, the materials become amorphous resulting in inefficient pulverization.

Next, with regard to the inside diameter, height, and thickness of the cap 2, appropriate dimensions of the cap need to be selected according to the operating temperature conditions, as the optimum diameter and height of the thermoelectric element differ depending on the operating temperature. However, from the viewpoint of ease of processing, the preferable dimensions of the cap are: inside diameter approximately 1 to 10 mm, height approximately 0.5 to 10 mm and thickness approximately 0.1 to 0.55 mm; and more preferable dimensions are: diameter approximately 1 to 3 mm, height approximately 0.5 to 3 mm and thickness 0.1 to 0.3 mm.

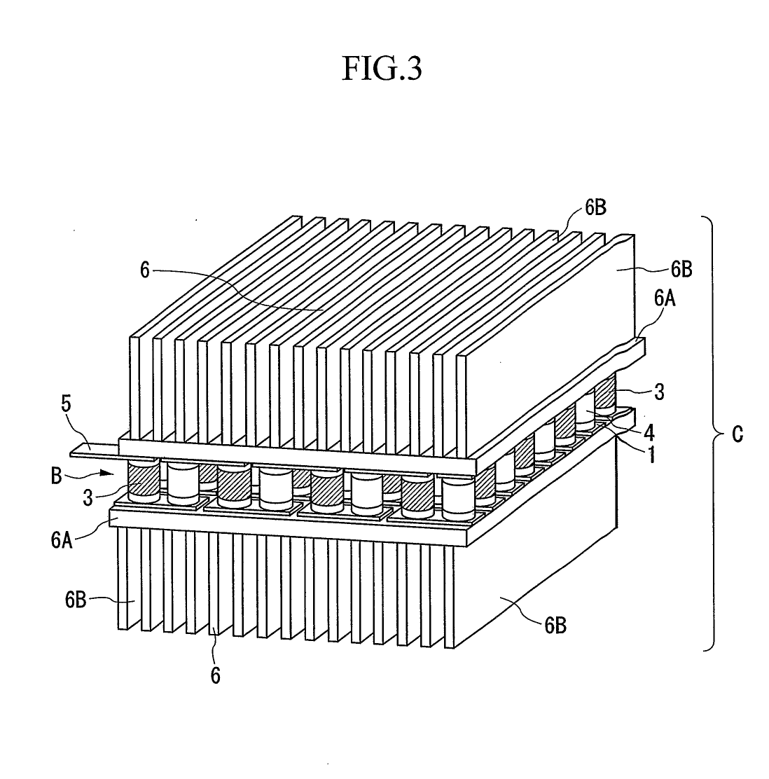

The constructions of the thermoelectric conversion module A and the thermoelectric power generating system that constitute preferred embodiments of the present patent application, are not particularly limited. However, for example, a thermoelectric conversion system C shown in FIG. 3 is one of examples of the present application.

For example, as shown in FIG. 3, the thermoelectric conversion system C is constructed by providing heat exchangers 6, such as heat sinks, on both sides of the thermoelectric conversion module set B, which is a combination of thermoelectric conversion modules A. Here, the heat exchangers 6 are constructed such that a plurality of finned materials 6B is provided in a standing condition on one side of substrates 6A, and if the substrates 6A are metal plates, it is preferable to arrange insulation materials (insulation layers) on the surface on the outside face side of each electrode 1 or on one side of the substrates 6A in order not to short-circuit the plurality of electrodes 1 of the thermoelectric conversion module set B.

Moreover, if direct current is applied to the thermoelectric conversion module set B in this configuration, one end becomes a low temperature and the other end becomes a high temperature. As a result, it can be used as a cooling and heating source or a thermoelectric power generating system.

The thermoelectric element 3, which is a p-type semiconductor, and the thermoelectric element 4, which is an n-type semiconductor, that construct the thermoelectric element are, for example, electrically connected in series or in parallel to construct the thermoelectric conversion module set B. The high temperature contacting part side of the constructed thermoelectric element is bonded to the heat exchanger 6 on the waste heat side via an insulating material. Meanwhile, the low temperature contacting part side of the constructed thermoelectric element is bonded to the heat exchanger 6 on the coolant side via an insulating material.

In the thermoelectric conversion system C constructed in this manner, the p-type semiconductor thermoelectric element 3 and the n-type semiconductor thermoelectric element 4 that are connected to the high temperature contacting part side and the low temperature contacting part side respectively, generate temperature differences, and electricity is generated by thermoelectric conversion according to the temperature differences based on the Seebeck effect.

By employing the thermoelectric conversion system C produced according to the present invention, the system can be used not only for large scale waste heat utilization in various types of industrial furnaces and incinerators, but also can be used for efficient utilization of various types of cogeneration, water heaters, car exhaust gas, and natural energies such as geothermal and solar heat, atomic energy and biomass energy.

As a result, the thermoelectric conversion module A according to the present invention is preferable for an exhaust heat recovery system, a solar heat utilization system, a Peltier cooling and heating system, a nuclear energy thermoelectric power generation system, and a biomass system.

The nuclear energy thermoelectric power generation system, for example, is capable of generating thermoelectric power by utilizing heat generated by nuclear decay as a high temperature heat source and outside as a low temperature side, and the nuclear energy thermoelectric power generation is applicable to a spacecraft using a radioisotope, for example. It is also possible to realize a thermoelectric power generation system by use of a biomass system as a heat source.

### EXAMPLE

The following will describe the present invention in more detail while referring to specific embodiments, so as to make the present invention understood more easily. However, the present invention is not limited to the embodiments described below.

As substances for constructing the thermoelectric elements, a substance mad from LaFe₄Sb₁₂ was used for the p-type thermoelectric element 3, and a substance made from CeCo₄Sb₁₂ was used for n-type thermoelectric element 4. These thermoelectric elements were processed into a column shape of diameter 1.7 mm×5.5 mm, using a centerless grinder. The used cap 2 was made from stainless steel (SUS304), the dimensions of which were diameter 1.6 mm×1.45 mm, and which had a plate bottom face.

Copper was used for a base material of the electrode 1, and nickel plating was applied to the base material, and, in addition, a gold film having a thickness of 5 nm was evaporated on the nickel plate for preparing a 5 mm×2 mm×0.2 mm flat plate.

As shown in FIG. 1, the caps 2 were mechanically pressed onto the thermoelectric elements 3 and 4 using a small vise to have the caps 2 fitted on the both ends. The height of the thermoelectric element after the caps had been fitted on the both ends was approximately 6.05 mm.

Silver solder was interposed between the thermoelectric elements 3 and 4 with the caps 2 fitted on the both ends, and the electrode 1, and they were subjected to heat application in an argon atmosphere at 700° C. for an hour to have them joined together as shown in FIG. 1.

The thermoelectric conversion module in the shape shown in FIG. 2 was produced by alternately electrically connecting a number of the p-type thermoelectric elements 3 and the n-type thermoelectric elements 4 shown in FIG. 1 in series.

As shown in FIG. 2, alumina plates having 0.5 mm thickness were provided on the top face side and bottom face side of the thermoelectric conversion module, and furthermore, the heat exchangers were placed on the top face side and the bottom face side. The heat exchangers on the top face and bottom face were fixed using bolts and nuts with springs (not shown in the diagram) to make the thermoelectric power generating system constructed as shown in FIG. 3.

By combining the thermoelectric conversion module produced in this manner, with a heat exchanger, a temperature difference is generated and thereby electric power can be generated. Moreover, when direct current is applied to this thermoelectric conversion module, one end becomes a low temperature and the other end becomes a high temperature. As a result, it can be used as a cooling or heating source.

By employing the present structure, a stress load can be absorbed by the caps pressed onto the both end sides of the thermoelectric element. Specifically, since the structure is configured to reduce a stress load, such that the electrodes are not fixed on the thermoelectric element and the caps can move a little while the caps are fitted on both end parts of the thermoelectric element, no changes in its performance are observed when filled Skutterudite sintered compacts are used for both the p-type and the n-type elements, and even after operating for 100 hours with one end at room temperature and the other end at 500° C., no cracks and so forth appeared on the thermoelectric element.

### COMPARATIVE EXAMPLE

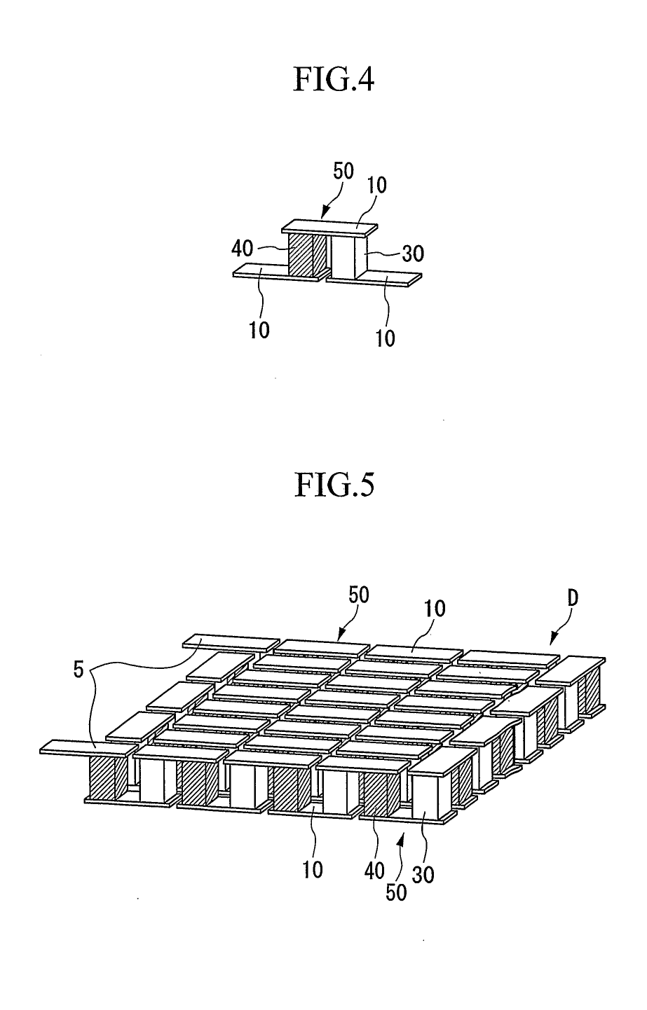

FIG. 4 shows a conventional thermoelectric conversion module as a comparative example, and FIG.5 shows an enlarged structure thereof.

In this example, rectangular column shaped thermoelectric elements 30 and 40 (width 2 mm×2 mm×5 mm) and electrodes 10 (the same as those of the working example above) were directly joined by silver solder. A thermoelectric conversion module set D constructed such that a plurality of thermoelectric conversion modules 50 having the structure described above were connected in series, was tested using filled Skutterudite sintered compacts for both the p-type and the n-type elements as described in the working example mentioned above, and it was operated for approximately one hour at room temperature for one end and at 500° C. for the other end. As a result, a gap appeared between the thermoelectric elements 30 and 40 and the electrodes 10, and the thermoelectric conversion module set D lost functionality This appears to have been due to the thermal stress load that occurred between the thermoelectric elements 30 and 40 and the electrodes 10, causing the silver soldered joint parts to separate.

### INDUSTRIAL APPLICABILITY

A thermoelectric conversion module of the present invention contributes to improvement of the performance of a Peltier cooling arid heating system or a thermoelectric power generating system.

1. A thermoelectric conversion module characterized in that an electrical connection of a thermoelectric element is carried out via a metal cap.

2. The thermoelectric conversion module according to claim 1, wherein each metal cap is integrally formed with an electrode of the thermoelectric element.

3. The thermoelectric conversion module according to claim 2, wherein an insulating material is coated on at least one surface of the electrode, and said cap is integrally connected to the face of said electrode that is not coated with the insulating material.

4. The thermoelectric conversion module according to claim 1, wherein a p-type thermoelectric element and an n-type thermoelectric element are alternately connected through respective electrodes, and said metal cap is respectively attached to both end parts of said p-type thermoelectric element and to both end parts of said n-type thermoelectric element, and said thermoelectric element and said electrode are connected through said metal caps.

5. The thermoelectric conversion module according to claim 1, wherein said thermoelectric element is configured in a block form, and said metal cap is attached to both end parts of the block form thermoelectric element.

6. The thermoelectric conversion module according to claim 4, wherein a plurality of said p-type thermoelectric elements and said n-type thermoelectric elements are connected through metal caps attached on both end parts, and a group of thermoelectric elements are arranged in a matrix configuration to form a thermoelectric conversion module set, and the electrodes on one side of each of said thermoelectric elements are arranged on one face side of said thermoelectric conversion module set, and the electrodes on the other side of each of said thermoelectric elements are arranged on the other face side of the arrayed thermoelectric conversion module set.

7. The thermoelectric conversion module according to claim 6, wherein a heat exchanger is placed on one face side of said thermoelectric conversion module set so as to contact with electrodes of respective thermoelectric elements through an insulating material, and a heat exchanger is placed on the other face side of said thermoelectric conversion module set so as to contact with electrodes of respective thermoelectric elements through an insulating material.

8. A thermoelectric power generating device comprising a thermoelectric conversion module according to claim 1.

9. A thermoelectric power generating method by utilizing a thermoelectric conversion module according to claim 1.

10. A waste heat recovery system comprising a thermoelectric conversion module according to claim 1.

11. A solar heat utilization recovery system comprising a thermoelectric conversion module according to claim 1.

12. A Peltier cooling and heating system comprising a thermoelectric conversion module according to claim 1.

13. A radioisotope thermoelectric power generation system comprising a thermoelectric conversion module according to claim 1.

14. A biomass system comprising a thermoelectric conversion module according to claim 1.

15. A thermoelectric element conversion element having at least one metal cap.
